(19) United States
(12) Patent Application Publication
(10) Pub. No.: US 2026/0036767 A1
(43) Pub. Date: Feb. 5, 2026

(54) EDGE COUPLING TO SURFACE COUPLING PHOTONICS DEVICE

(71) Applicant: XILINX, INC., San Jose, CA (US)

(72) Inventors: Chuan XIE, Fremont, CA (US); Hao-Hsiang LIAO, San Jose, CA (US); Fang-Yu LIANG, Hsinchu City (TW); Suresh RAMALINGAM, Fremont, CA (US)

(21) Appl. No.: 18/789,629

(22) Filed: Jul. 30, 2024

(51) Int. Cl. G02B 6/42; H01L 23/00; H01L 25/16

(52) U.S. Cl. CPC G02B 6/4214; G02B 6/423; H01L 24/16; H01L 25/167; H01L 2224/16225; H01L 2924/1431

(57) ABSTRACT

A photonics device, a co-packaged device, and a computer system that provide wide spectral range optical coupling and methods for using the same are disclosed herein. In one example, a photonics device is provided that includes a device and dielectric layer, and a first coupling device. The device and dielectric layer includes a first recess within a first surface of the device and dielectric layer, and a second recess within the first surface of the device and dielectric layer. The first coupling device is mounted to the first surface of the device and dielectric layer. The first coupling device includes a first mounting element and a first extended region. The first mounting element is disposed within the first recess and the first extended region is disposed within the second recess. The first extended region is configured to reflect an optical signal through the device and dielectric layer.

### TECHNICAL FIELD

Examples of the present disclosure generally relate to a photonics device that receives an optical signal via an edge coupling and outputs an optical signal via surface coupling.

### BACKGROUND

A co-packaged optics (CPO) device integrates optical elements with electric integrated circuit (IC) elements within a single packaged device. The optical circuits are made with silicon photonics (SiPh) elements. The die containing the photonics circuits may be referred to a photonics IC (PIC). CPO devices provide high bandwidth, low latency, and power efficient data communication. CPO devices are used within data centers, and in other computer systems to support increase data communication speeds (e.g., of about 400 gigabits per second (Gbps)). CPO devices are used as front-end networks used for connecting server computing systems in data centers.

CPO devices face manufacturing difficulties including coupling light into and out of the packaged device with low loss. In a wavelength division multiplexing (WDM) system, the coupling of light into and out of the device has a wide wavelength window, or is wavelength independent. In a WDM device, multiple optical channels are carried in a common waveguide and optical fiber.

A PIC device includes a die having a substrate. A PIC device receives and outputs optical signals. A PIC device is coupled to a fiber element or other optical elements to allow for optical signals to be received and output. A PIC device may be coupled to an optical element via surface coupling or edge coupling. In surface coupling, an optical signal from the PIC is emitted vertically to the substrate (or wafer) of the PIC device. Surface coupling is implemented with surface gratings known as grating couplers. Grating couplers have a minimum coupling loss (typically exceeds 1 dB). Further, grating couplers having a limited wavelength window. In edge coupling, an optical signal from the PIC is enters or leaves in the direction parallel to the surface of the die (wafer) from the edge of the die of the PIC device.

From the standpoint of light coupling to (from) the PIC from (to) the optical fibers, the manufacturability of surface coupling is greater than that of edge coupling. This is in part because the surface of the PIC die provides a good reference plan for the coupling optics, or the fiber assembly unit (FAU), so that the coupling optics' degrees of freedom for adjustment (alignment) are reduced. However, surface coupling devices based on grating couplers have a greater loss of light as compared to edge coupling because of the intrinsic loss of the coupler, and a restricted wavelength window due to the multi-beam interference nature of the coupler. The PIC device described in the following incorporates the manufacturability of surface coupling with the improved performance of edge coupling.

### SUMMARY

A photonics device, a co-packaged device, and a computer system that provide wide spectral range optical coupling and methods for using the same are disclosed herein. In one example, a photonics device is provided that includes a device and dielectric layer, and a first coupling device. The device and dielectric layer includes a first recess within a first surface of the device and dielectric layer, and a second recess within the first surface of the device and dielectric layer. The first coupling device is mounted to the first surface of the device and dielectric layer. The first coupling device includes a first mounting element and a first extended region. The first mounting element is disposed within the first recess and the first extended region is disposed within the second recess. The first extended region is configured to reflect an optical signal through the device and dielectric layer.

In another example, a co-packaged device is provided. The co-packaged device includes a package substrate, an integrated circuit device, and a photonics device. The integrated circuit device is mounted to the package substrate. The photonics device is mounted to the package substrate and connected to the integrated circuit device. The photonics device includes a device and dielectric layer, and a first coupling device. The device and dielectric layer includes a first recess within a first surface of the device and dielectric layer and a second recess within the first surface of the device and dielectric layer. The first coupling device is mounted to the first surface of the device and dielectric layer. The first coupling device includes a first mounting element and a first extended region. The first mounting element is disposed within the first recess and the first extended region is disposed within the second recess. The first extended region is configured to reflect an optical signal through the device and dielectric layer.

In another example, a computer system is provided. The computer system includes computing devices and a co-packaged device coupled to the computing devices. The co-packaged device is configured to communicate signals to and from the computing devices. The co-packaged device includes a package substrate, an integrated circuit device, and a photonics device. The integrated circuit device is mounted to the package substrate. The photonics device is mounted to the package substrate and connected to the integrated circuit device. The photonics device includes a device and dielectric layer, a first coupling device. The device and dielectric layer has a first recess within a first surface of the device and dielectric layer and a second recess within the first surface of the device and dielectric layer. The first coupling device is mounted to the first surface of the device and dielectric layer. The first coupling device includes a first mounting element and a first extended region. The first mounting element is disposed within the first recess and the first extended region is disposed within the second recess. The first extended region is configured to reflect an optical signal through the device and dielectric layer.

These and other aspects may be understood with reference to the following detailed description.

### BRIEF DESCRIPTION OF THE DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 illustrates a block diagram of a photonics integrated circuit having a coupling device.

FIG. 2 illustrates a block diagram of a coupling device.

FIG. 3 illustrates a block diagram of a photonics integrated circuit having a coupling device.

FIG. 4 illustrates a block diagram of a photonics device having a coupling device, and configured for edge coupling and surface coupling.

FIG. 5 illustrates a block diagram of a photonics device having a multiple coupling devices, and configured for edge coupling and surface coupling.

FIG. 6 illustrates a block diagram of a photonics device having a multiple coupling devices, and configured for edge coupling and surface coupling.

FIG. 7 illustrates a block diagram of a co-packaged device.

FIG. 8 illustrates a block diagram of a computer system including a co-packaged device.

FIG. 9 illustrates a flowchart of a method for forming a photonics integrated circuit.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the features or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

A photonics device may be a co-packaged optics (CPO) device. In a CPO device incorporates one or more photonics devices (e.g., photonics integrated circuits (PICs)) and an electronic IC device into a single packaged device. CPO devices are used in computing systems to transmit and receive data at high speeds. For example, CPO devices are used in data centers as interconnection devices and other devices. A CPO device increases the interconnecting bandwidth density and energy efficiency by reducing the electrical link length by packaging optical and electrical devices within a common package.

CPO devices are implemented within data center and other distributed computing systems. In one or more examples, CPO devices are used as front-end networks used for connecting server computing systems in data centers. In one example CPO application, fiber elements (e.g., optical fibers or other optical elements) are attached to a silicon substrate. The fiber elements provide a pathway for optical signals to be received by and output by the CPO device. Loss of light (e.g., optical signal) may occur where a fiber element is connected to the CPO device (e.g., connected to the substrate). Loss of optical power that occurs when light transitions from the optical fiber and the PIC is referred to as coupling loss. Coupling loss may be dependent on the wavelength or the polarization of light. Surface coupling or edge coupling may be used to connect fiber elements to a CPO device. In surface coupling, an optical signal travels pseudo perpendicularly to the surface of the PIC die (wafer). In one or more examples, the light passes through the silicon substrate. In edge coupling, an optical signal travels parallel to the surface of the PIC die from the edge of the die of the CPO device.

While edge coupling potentially provides higher performance (e.g., no overhead loss, wide wavelength window, low polarization dependency, etc.) than surface coupling, edge coupling is generally more difficult to achieve good alignment between the edge coupler and the optical fiber. During manufacturing, active alignment with adjustment in multiple degrees of freedom provides device with improved performance. Alignment difficulties make edge coupling less viable for high volume manufacturing than surface coupling. Surface coupling for photonics, which is implemented with surface gratings, or grating couplers, is easier to align than edge coupling. In some examples where an expanded beam is used for passive alignment is sufficient, which significantly reduces cycle time. However, due the coupling loss of grating couplers and/or limited wavelength window of grating couplers, photonics devices incorporating surface coupling have a lower performance than photonics devices incorporating edge coupling.

An edge coupled photonics device may incorporate V-grooves for fiber attachment. While V-grooves may eliminate the need for active alignment, V-grooves do not reduce cycle time, lower assembly cost, and/or improve manufacturing yield. Thus, the use of V-grooves does not provide a solution for high volume manufacturing. Further, V-grooves are not compatible with through-silicon-vias (TSVs), are not detachable, and have limited support for optical fiber pitch.

In the following, a photonics device that incorporates edge coupling with the improved manufacturability of surface coupling is described. The photonics device described herein retains the wavelength independency of edge coupling, while allowing manufacturing techniques developed for surface coupling to be applied, increasing the manufacturing throughput and yield. During the manufacturing of the photonics device described herein, no active alignment is used, increasing the manufacturing throughput and yield. Further, the photonics device described herein may be configured as a detachable fiber assembly unit (FAU). In one or more examples, the photonics device has optical coupling couplers proximate where an optical transceiver die may attach to the package substrate.

The photonics device described herein has improved performance within a wavelength division multiplexing (WDM) configuration. The photonics device described herein provides wide spectral range optical coupling. In a WDM configuration, an optical signal coupled into and out of the device has a wide wavelength spread, hence the coupling scheme must have a wide wavelength window, or be wavelength independence. In a WDM configuration, multiple optical channels (of different wavelengths) are carried in a common waveguide and optical fiber within the photonics device.

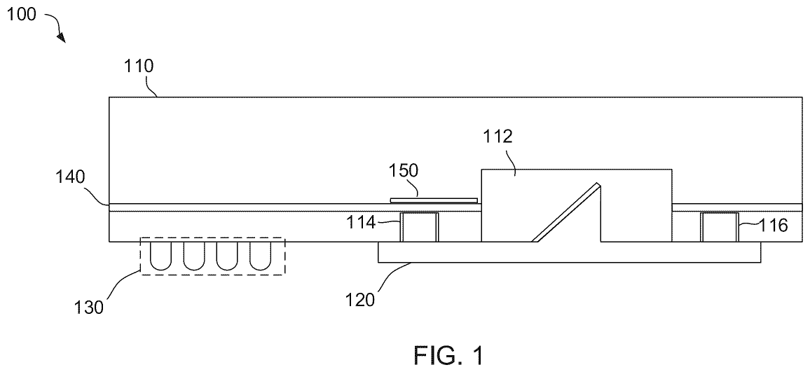

FIG. 1 illustrates a photonics device 100, according to one or more examples. The photonics device 100 includes substrate (e.g., wafer) 110, coupling device 120, connecting elements (solder bumps or copper pillars) 130, buried oxide (BOX) layer 140 of a silicon-on-insulator wafer, and converter device (e.g., optical spot-size converter device) 150. In one example, the photonics device 100 receives and outputs an optical signal. In such an example, the BOX layer 140 serves as the cladding layer for the silicon waveguides above the BOX layer 140.

The photonics device 100 may be referred to as a PIC device. In one or more examples, the photonics device 100 is a PIC device which contains the photonics circuits for the CPO. In FIG. 1, the photonics circuits are not shown except for the converter device 150 as the rest of the circuit elements are not related to coupling of light in and out of the PIC. In one example, the photonics device 100 is referred to as a silicon photonics (SiPh) chip. The photonics device 100 includes a die body defined by the device and dielectric layer 110.

The photonics device 100 contains an optical connecting device that couples a fiber element (or another photonics element) with a processing device, and/or another electronic device. In one example, the photonics device 100 is part of an interconnection device for a data center or other distributed computing device. In another example, the photonics device 100 is part of another computing element within a data center or other distributed computing device.

The device and dielectric layer 110 one or more dielectric layers (e.g., silicon oxide), the BOX layer 140, a silicon photonics device layer, and/or back-end-of-line (BEOL) dielectrics. The BEOL dielectrics are deposited on the silicon photonic device layer. The silicon photonics device layer is disposed above the BOX layer 140. The silicon photonics device layer may be the same height as the Box layer 140. In other examples, the device and dielectric layer 110 may include other elements additionally or alternatively the layers described above. Further, in other examples, the device and dielectric layer 110 may have a different configuration of layers that that described above. In another example, the device and dielectric layer 110 is formed of other materials.

The BOX layer 140 is embedded within device and dielectric layer 110. Further, the converter device 150 is embedded within the device and dielectric layer 110. The converter device 150 is an edge coupler spot size converter device. The converter device 150 converts the small optical mode in the strongly confined high index contrast silicon waveguide (e.g., the BOX layer 140) to a mode size more easily coupled into the fiber element, which has a larger mode field size.

The recess (trench) 112 is etched from the bottom of 110. The etch depth of 112 goes beyond 150 to create a facet for edge coupling (for light to go in and out of the photonics device 100). Shallower trenches (recesses) 114 and 116 are etch from the bottom of 110 to the bottom side of the BOX layer 140. The coupling device 120 is mounted to the device and dielectric layer 110 via the recesses 112, 114, and 116. In one example, the substrate includes more than three recesses 112, 114, and 116.

The connecting elements 130 are used to form a mechanical and/or electrical connection with another device (e.g., substrate). In one example, the connecting elements are solder balls. A reflow process is used to connect the connecting elements 130 with another device.

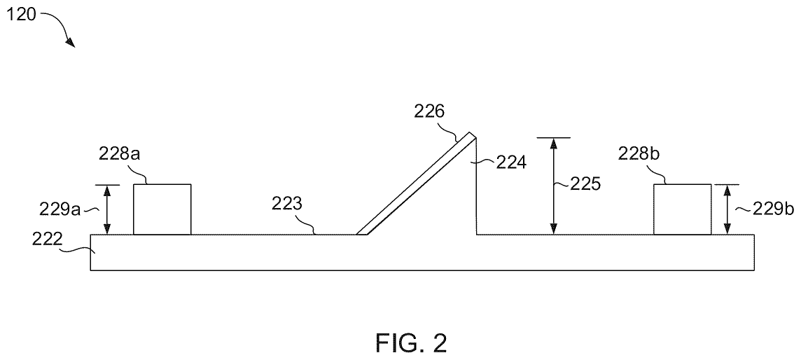

FIG. 2 illustrates the coupling device 120, according to one or more examples. As is illustrated in FIG. 2, the coupling device 120 includes substrate 222, extended region 224, reflective element 226, and mounting elements 228a, 228b. The substrate 222 is formed from a glass material. In other examples, the substrate 222 is formed from other transparent materials. In one or more examples, the substrate 222 is formed from a partially transparent, or semi-transparent, material or non-transparent material.

The extended region 224 extends from the surface 223 of the substrate 222. As is illustrated in FIG. 2, the extended region 224 has a triangular shape. In other examples, the extended region 224 has other shapes that are able to support the reflective element 226. The reflective element 226 deflects light from the edge coupler facet of the photonics device 100 from the horizontal (parallel to die surface) to vertical (perpendicular to die surface) direction, converting edge coupling to a surface coupling. For example, the extended region 224 may have any number of sides, where at least one side is angled to support the reflective element 226 to guide light from the converter device 150 out of the photonics device 100.

The reflective element 226 is formed on (e.g., disposed on) a surface of the extended region 224. In one example, the reflective element 226 is a micro mirror. The extended region 224 may be 3D printed on substrate 222. The micro mirror 226 has a metal coated reflective surface. The reflective element 226 may be a defecting mirror. In one or more examples, the reflective element 226 is metal coated. In one or more examples, the reflective element 226 has a curved (e.g., concave) surface. In other examples, the reflective element 226 is not limited to being a micro mirror and may be any type of reflective element that is able direct an optical signal received from converter device 150 away from the surface 223.

The position of the reflective element 226 and the extended region 224 provides for a deflected beam to have a desirable diameter and is collimated.

In one example, the extended region 224 may have a different shape and/or size than that illustrated in FIG. 2. For example, the extended region 224 has one or more curved (e.g., concave) regions. In such an example, the extended region 224 may have one or more curved regions to support one or more edge couplers in a linear array along the edge of the PIC die. In another example, the extended region 224 has one or more angled regions. The different angled regions may differ in the corresponding angle, shape, and/or size. An extended region 224 may have multiple surfaces having a reflective element mounted thereon.

The mounting elements 228a and 228b are disposed on (e.g., mounted to) the surface 223 of the substrate 222. The mounting elements 228a and 228b may be formed from the same material as the substrate 222, or a different material. In one example, the mounting elements 228a and 228b are formed from the same material as the substrate 222, or a different material. While two mounting elements 228 are illustrated, in other examples, more than two mounting elements 228 may be included within the coupling device 120. Further, the location of the mounting elements 228 may differ from that illustrated in FIG. 2. For example, the mounting elements 228 are mounted the same distance from an edge of the substrate 222. In other examples, at least one mounting element 228 is mounted a different distance from another mounting element 228 from the edge of the substrate 222.

The extended region 224 has a height 225 that extends from the surface 223. The mounting elements 228a and 228b have a height 229a and 229b, respectively, which extend from the surface 223. In one example, the mounting elements 228a and 228b have the same height. In other examples, at least one mounting element 228 has a height that differs from another mounting element. The height 225 is greater that the height 229a and/or 229b. In other examples, the height 225 is equal to or less than the height 229a and/or 229b.

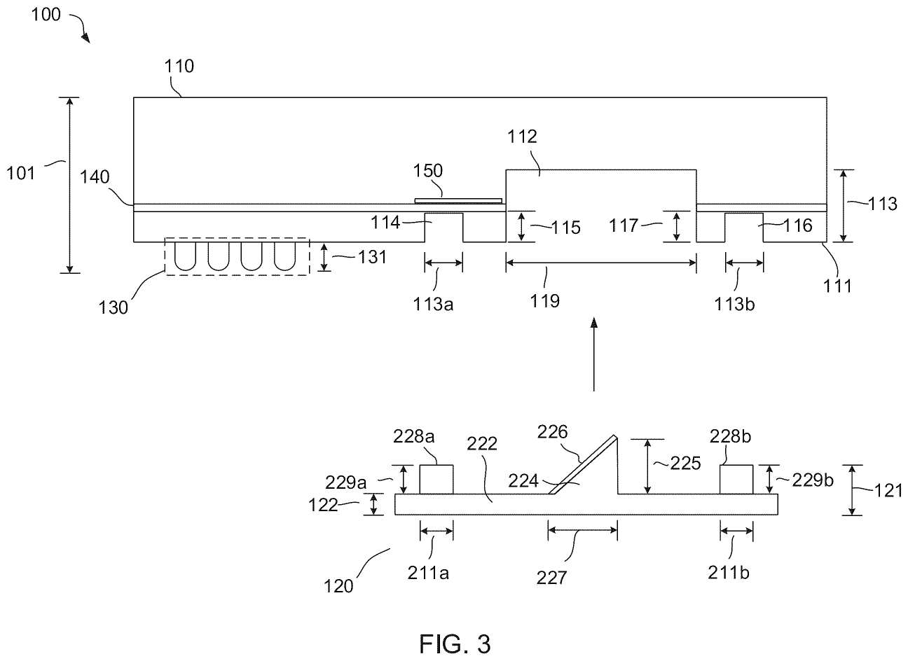

In the example of FIG. 3, the coupling device 120 is shown separate from the device and dielectric layer 110 to illustrate the relationships of the elements of the coupling device 120 relative to the device and dielectric layer 110.

To mount the coupling device 120 to the device and dielectric layer 110, the mounting element 228a is disposed within the recess 114 and the mounting element 228 is disposed within the recess 116. An adhesive may be disposed within the recesses 114 and 116 and/or on the mounting elements 228a and 228b and used to mount the coupling device 120 to the device and dielectric layer 110. For example, when the mounting elements 228a and 228b are inserted within the recesses 114 and 116, the adhesive bonds (or holds) the coupling device 120 to the device and dielectric layer 110. In other examples, materials other than an adhesive maybe used to bond the coupling device 120 to the device and dielectric layer 110.

As is illustrated in FIG. 3, the recess 114 has a height of 115 from the surface 111 of the device and dielectric layer 110, the recess 116 has a height of 117 from the surface 111. In one example, the height 115 and the height of 116 is from the surface 111 to the bottom of the BOX layer 140. The height 115 is greater than, equal to, or less than the height 117. In one example, the heights 115, 117, 139a, and 139b are sized to allow the mounting elements 228a and 228b to be disposed within the recesses 114 and 116, respectively, and bond the coupling device 120 to the device and dielectric layer 110.

The coupling device 120 is mounted to device and dielectric layer 110 such that the reflective element 226 and the extended region 224 are disposed within the recess 112. The recess 112 has a height of 113. The height 113 is greater than the height 225. As the height 113 is greater than the height 225, the extended region 224 and the reflective element 226 can be disposed within the recess 112 without contacting the device and dielectric layer 110. In one example, the height 113 and the height 225 allow for the reflective element 226 and/or the extended region 224 to contact the device and dielectric layer 110. In one or more examples, the recess 112 is filled with an index matching adhesive.

The recess 112 has a width 119. The width 119 is greater than a width 227 of the extended region 224 and the reflective element 226. The recess 114 has a width 113a and the recess 116 has a width 113b. The width 113a is greater than, less than, or equal to the width 113b. The mounting element 228a has a width 211a and the mounting element 228b has a width 211b. The width 211a is greater than, less than, or equal to the width 211b. The width 113a is greater than the width 211a. The width 113b is greater than the width 211b.

The connecting elements 130 have a height of 131 from the surface 111. The height 131 is greater than the height 122. Accordingly, when the coupling device 120 is mounted to the surface 111 of the device and dielectric layer 110, the substrate 222 does not extend beyond outer edge of the connecting elements 130, allowing the connecting elements 130 to form bonds to connect the photonics device 100 with another device.

The photonics device 100 has a thickness of 101. In one example, the thickness 101 is 100 μm. In another example, the thickness 101 is greater than or less than 100 μm. The substrate 122 has a thickness 122. In one example, the thickness 122 is 50 μm. In other examples, the thickness is greater than or less than 50 μm.

In one or more examples, the thickness and/or flatness of an oxide deposited bellow the BOX layer 140. However, due to the limitations in manufacturing, the thickness and/or flatness of the oxide may vary from photonics device to photonics device. Accordingly, the oxide is etched, or removed in another way, to properly position the coupling device 120 with the device and dielectric layer 110 to maintain the thickness 101 within manufacturing and/or design guidelines.

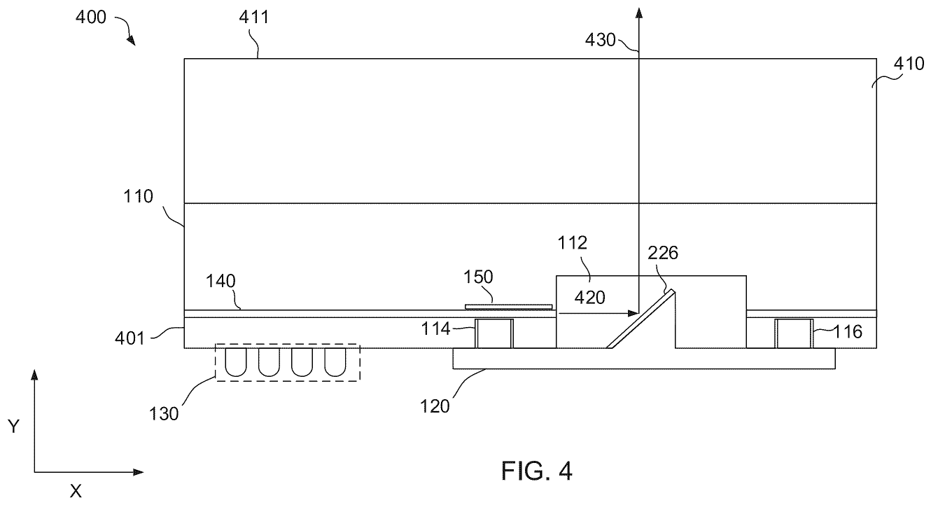

FIG. 4 illustrates a photonics device 400. The photonics device 400 includes the device and dielectric layer 110, the coupling device 120, and a substrate 410. The substrate 410 is coupled (e.g., connected or bonded) to the device and dielectric layer 110. The substrate 410 is a silicon substrate.

The coupling device 120 allows for an optical signal (e.g., light signal) to be received via an edge of the photonics device 400 and output from a top surface of the photonics device 400. In one example, an optical signal 420 is enters the photonics device 400 via the converter device 150 along the X axis at and the optical signal 430 is output along the Y axis from the surface 411 of the photonics device 400. In another example, an optical signal is received and reflected and focused via reflective element 226 and output to the converter device 150.

In one example, the substrate 410 is thinned to improve alignment tolerances during manufacturing, increasing the manufacturability of the photonics device 400, and mitigating the loss of light within the photonics device 400.

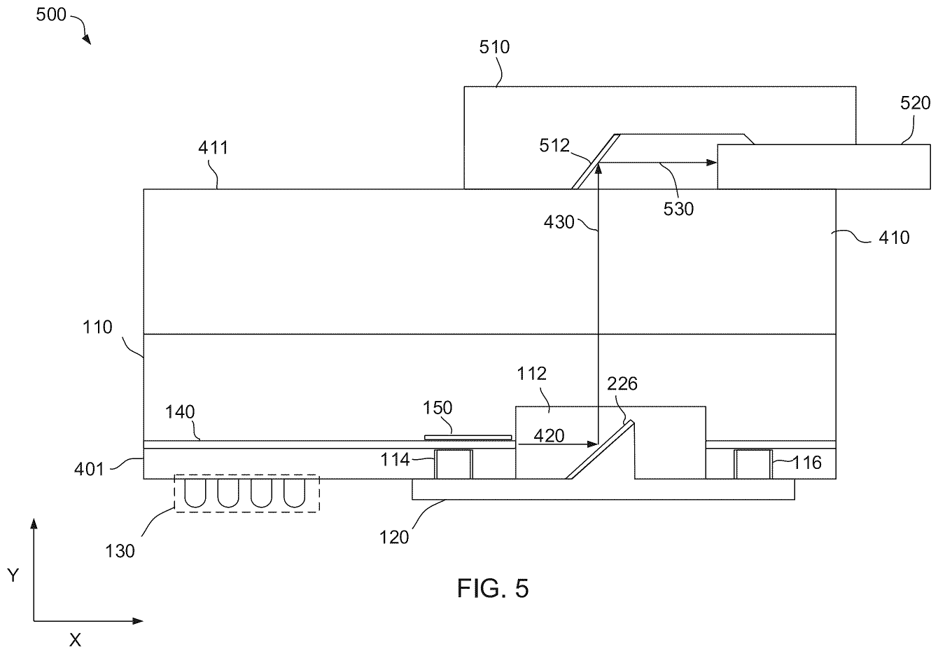

FIG. 5 illustrates a photonics device 500. The photonics device 500 includes the device and dielectric layer 110, the coupling device 120, the substrate 410, the coupling device 510, and the fiber element 520. The substrate 410 is coupled (e.g., connected or bonded) to device and dielectric layer 110. The coupling device 510 and the fiber element 520 are bonded via an adhesive or another bonding agent. The coupling device 510 and the fiber element 520 are coupled to the surface 411 of the substrate 410.

The coupling device 510 includes reflective element 512. The reflective element 512 is configured similar to the reflective element 226. The reflective element 512 reflects and focuses the optical signal 430 into the optical signal 530. The optical signal 530 is output to the fiber element 520. The optical signal 430 is received along the Y axis and is output as the optical signal 530 along the X axis. The optical signal 530 is output via the fiber element 520. In another example, an optical signal is received via the fiber element 520 from an external device and output to the reflective element 512. The reflective element 512 reflects and focuses the received the optical to the reflective element 226, which reflects and focuses the optical signal to the converter device 150. In such an example, the optical signal follows path indicated by 530, 430, and 420 in a reverse direction.

The incorporation of the coupling device 120 within the photonics device 500 allows the photonics device 500 to receive an optical signal via edge coupling and outputs an optical signal via surface coupling. Accordingly, the photonics device 500 has the improved manufacturability of surface coupling device and the improved optical performance of an edge coupling device.

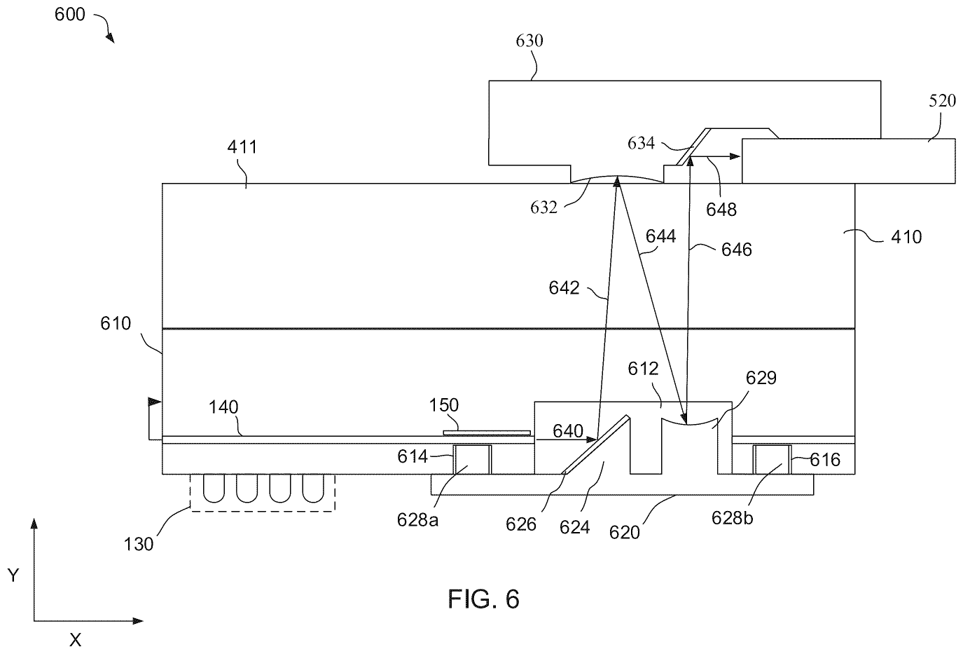

FIG. 6 illustrates a photonics device 600, according to one or more examples. The photonics device 600 includes the device and dielectric layer 610, coupling device 620, substrate 410, coupling device 630, and the fiber element 520.

The 610 is configured similar to the device and dielectric layer 110 of FIG. 1. For example, the device and dielectric layer 610 includes recesses 612, 614, and 616 that are configured similar to the recesses 112, 114, and 116. As is described with regard to the recesses 112, 114, and 116, the recesses 612, 614, and 616 enable the coupling device 620 to be mounted to the device and dielectric layer 610.

The coupling device 620 is configured similar to the coupling device 120 of FIG. 1. For example, the coupling device 620 includes mounting elements 628a and 628b. The mounting elements 628a and 628b are configured similar to the mounting elements 228a and 228b. The mounting elements 628a and 628b are mounted within the recesses 614 and 616, respectively, to mount the coupling device 620 with the device and dielectric layer 610.

The coupling device 620 includes extended region 624 and reflective element 626. The extended region 624 and the reflective element 626 are configured similar to the extended region 224 and reflective element 226 of FIG. 2. Further, the coupling device 620 includes reflective element 629. The reflective element 629 has a curved surface to guide light received from the coupling device 620. While the coupling device 620 is illustrated with a particular configuration of extended regions 624 and reflective elements 629, in other examples, the coupling device 620 may have a different configuration of reflective elements and/or include reflective elements not illustrated in FIG. 6.

The coupling device 630 is mounted to the surface 411 of the substrate 410. The coupling device 630 includes reflective elements 632 and 634. The reflective element 632 has a curved surface, and guides line to the coupling device 620. The reflective element 634 is configured similar to the reflective element 512 of FIG. 5. While the coupling device 630 is illustrated with a particular configuration of reflective elements 632 and 634, in other examples, the coupling device 630 may have a different configuration of reflective elements and/or include reflective elements not illustrated in FIG. 6.

The photonics device 600 receives the optical signal 640. The optical signal 640 is guided by the reflective element 626 toward the reflective element 632 as the optical signal 642. The optical signal 642 is guided by the reflective element 632 to the reflective element 629 as the optical signal 644. The optical signal 644 is guided by the reflective element 629 to the reflective element 634 as the optical signal 646. The optical signal 646 is guided by the reflective element 634 to the fiber element 520 as the optical signal 648. The fiber element 520 receives the optical signal 648. The fiber element 520 transmits the optical signal 648 to a photonics device external to and coupled with the photonics device 600. In one example, the fiber element 520 receives an optical signal from an external source and provides (e.g., outputs) the optical signal to the reflective element 634. The optical signal is reflected and focused by the reflective element 634 and provided (output) to the reflective element 629. The optical signal is reflected and focused by the reflective element 629 and provided (output) to the reflective element 632. The optical signal is reflected and focused by the reflective element 632 and provided (output) to the reflective element 626. The optical signal is reflected and focused by the reflective element 626 and provided (output) to the converter device 150. In such an example, the optical signal follows along the path indicated by 648, 646, 644, 642, and 640 in reverse.

The incorporation of the coupling device 620 within the photonics device 600 allows the photonics device 600 to receive an optical signal via edge coupling and outputs an optical signal via surface coupling. Accordingly, the photonics device 600 has the improved manufacturability of surface coupling device and the improved optical performance of an edge coupling device. The reflective element 629 and the reflective element 632 generate additional reflections of the optical signal, improving the tolerance to the placement inaccuracy of coupling device 630 relative to the surface 411, improving the manufacturing yield of the photonics device 600.

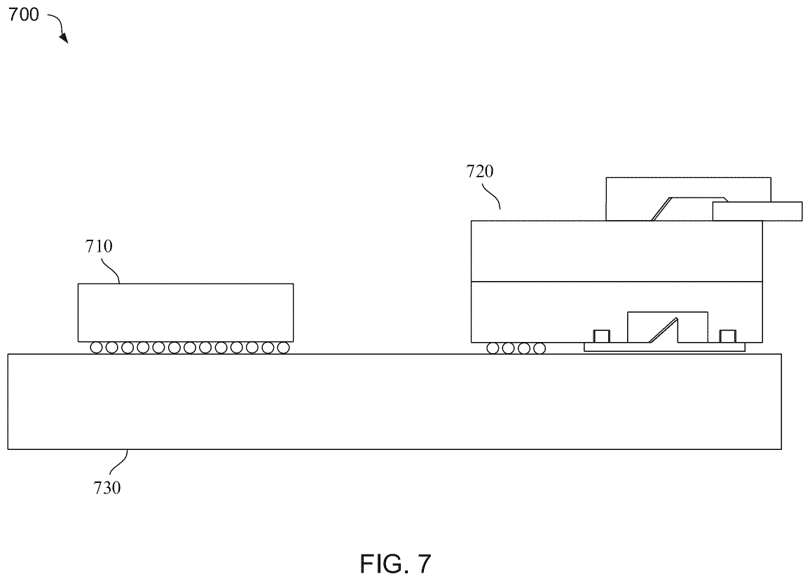

FIG. 7 illustrates a co-packaged device (e.g., co-packaged optical device) 700, according to one or more examples. The co-packaged device optical 700 includes processing device 710, photonics device 720, and package substrate 730. The processing device 710 is mounted to the package substrate 730. The processing device 710 is an IC device. In one example, the processing device 710 is a central processing unit (CPU), a graphics processing unit (GPU), or a data switch, among others. In one or more examples, the processing device 710 represents one or more processors such as a microprocessor, a CPU, GPU, data switches, or the like. In one or more examples, the processing device 710 may be complex instruction set computing (CISC) microprocessor, reduced instruction set computing (RISC) microprocessor, very long instruction word (VLIW) microprocessor, or a processor implementing other instruction sets, or processors implementing a combination of instruction sets. In one or more examples, the processing device 710 may also be one or more special-purpose processing devices such as an application specific integrated circuit (ASIC), a field programmable gate array (FPGA), a digital signal processor (DSP), network processor, or the like.

The photonics device 720 is mounted to the IC package substrate 730. In one or more examples, with reference to FIG. 1, the connecting elements 130 may be solder balls and reflowed (or adhered in some other way) to mount the photonics device 720 to the IC package substrate 730. The photonics device 720 may be configured similar to the photonics device 500 of FIG. 5 or the photonics device 600 of FIG. 6.

The IC package substrate 730 is an organic substrate a silicon interposer. In one example, the IC package substrate 730 is referred to as a package substrate. The IC package substrate 730 includes one or more metal layers and/or vias that are used to couple the processing device 710 with the photonics device 720. Signals are communicated from the processing device 710 to the photonics device 720 through the vias and metal layers within the IC package substrate 730.

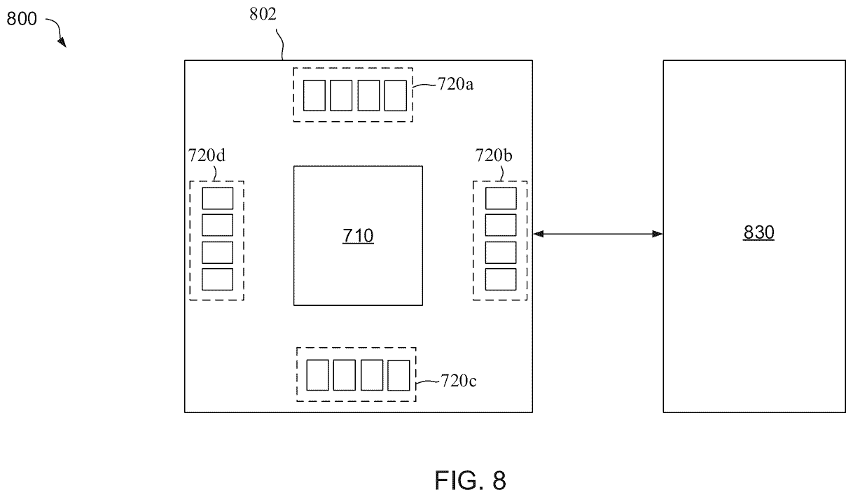

FIG. 8 illustrates computer system 800, according to one or more examples. The computer system 800 includes the co-packaged device 802 including the processing device 710 and one or more photonics device groups 720, and computer devices 830. The photonics devices 720 are optical transceiver devices. For example, the photonics devices 720 are used to transmit and/or receive data. In one or more examples, the photonics devices 720 are part of an interconnect within the computer system 800 and/or between the computer system 800 and other computer systems. The photonic device groups 720 include one or more photonic devices 720. The co-packaged device 802 is illustrated as including four photonics devices within each photonics device groups 720a-d, but in other examples, the co-packaged device 802 may include more than or less than four photonics devices in one or more of the photonics device groups 720a-d. In one example, the computer system 800 is a server in a data center or a distributed computing system, and the co-packaged device 802 is the data processing or computing unit with the photonic devices 720 functioning as optical transceivers providing an interconnect circuitry between the computer devices 830 and network devices and/or other computer devices external to the computer devices 830. For example, the co-packaged device 802 is disposed between the computer devices 830 (e.g., server devices) and a network. In other examples, the co-packaged device 802 is disposed in other locations. In one example, the co-packaged device 802 communicates signals to and from the computer devices 830 and other computer devices that are connected to the co-package device 802 via a network connect or other connection type. In one example, the computer system 800 includes one or more co-packaged devices 802.

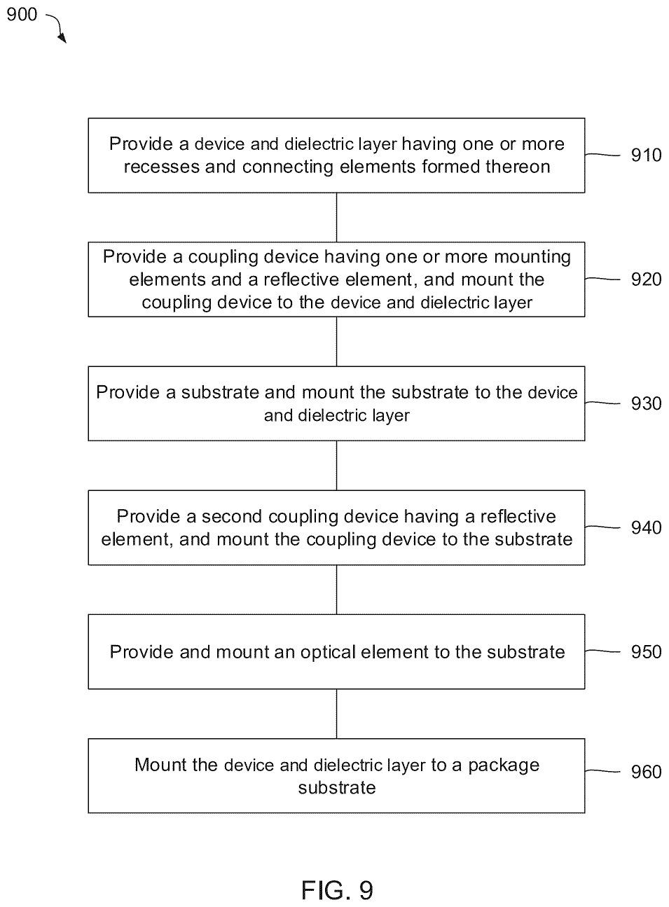

FIG. 9 illustrates a flowchart of a method 900, according to one or more examples. The method 900 is performed during the manufacturing process of a photonics device (e.g., the photonics device 500 of FIG. 5 or the photonics device 600 of FIG. 6) or a co-packaged optical device (e.g., the co-packaged optical device 700 of FIG. 7). In one example, the method 900 is performed by a semiconductor manufacturing company.

At 910 of the method 900, a device and dielectric layer having one or more recesses and connecting elements formed thereon is provided. The connecting elements and recesses are disposed on and formed in a first side of substrate. In one example, the substrate is the device and dielectric layer 110 of FIG. 1, FIG. 3, FIG. 4, or FIG. 5, or the device and dielectric layer 610 of FIG. 6. The connecting elements (e.g., the connecting elements 130) are formed on the surface of the device and dielectric layer 110 or 610. The recesses 114 or 614 are formed via an etching, or another material removal process) in the device and dielectric layer 110 or device and dielectric layer 610.

At 920 of the method 900, a coupling device having one or more mounting elements and a reflective element is provided, and the coupling device is mounted to the device and dielectric layer. The coupling device is the coupling device 120 of FIG. 1, FIG. 2, FIG. 3, FIG. 4, or FIG. 5, or the coupling device 620 of FIG. 6. The coupling device 120 or 620 is mounted to the device and dielectric layer 110 or 610 as illustrated in FIG. 5 or FIG. 6. The coupling device 120 or 620 is mounted (bonded) to the device and dielectric layer 110 or 610 via an adhesive material or another bonding agent. In one example, the mounting elements 228 or 628 are mounted to the corresponding recesses 114 or 614 via an adhesive later or another bonding agent to mount the coupling device 120 or 620 to the device and dielectric layer 110 or 610. Additionally, or alternatively, an adhesive material or another bonding agent is applied to a surface of the coupling device 120 or 620 and/or the device and dielectric layer 110 or 610 and used to mount (e.g., bond) the coupling device 120 or 620 with the device and dielectric layer 110 or 610.

At 930 of the method 900, a substrate is provided and the substrate is mounted to the device and dielectric layer. For example, as illustrated in FIG. 4, FIG. 5, and FIG. 6, the substrate 410 is provided and mounted to the device and dielectric layer 110 or 610. In one example, the substrate 410 is bonded to the device and dielectric layer 110 or 610 via an adhesive material, or another bonding agent. The adhesive material (or another bonding agent) is applied to the surface of the substrate 410 and/or the surface of the device and dielectric layer 110 or 610, to mount the substrate 410 with the device and dielectric layer 110 or 610.

At 940 of the method 900, a second coupling device is provided and mounted to the substrate. The second coupling device has a reflective element. In one example, the second coupling device has one or more reflective elements. The second coupling element may be the coupling device 510 of FIG. 5 and/or the coupling device 630 of FIG. 6. In one example, the coupling device 510 or the coupling device 630 is mounted to the substrate 410 via an adhesive material, or another bonding agent, formed on the coupling device 510 or 630 and/or the substrate 410.

At 950 of the method 900, an optical element is provided and mounted to the substrate. For example, the fiber element 520 of FIG. 5 or FIG. 6 is provided and mounted to the substrate 410. The coupling device 510 is mounted via an adhesive material, or another bonding agent, that is applied to the substrate 410 and/or the fiber element 520.

At 960 of the method 900, the device and dielectric layer is mounted to the package substrate. For example, with reference to FIG. 5, FIG. 6, and/or FIG. 7, the device and dielectric layer 110 or 610 is mounted to the package substrate 730. In one example, a reflow process is used to mechanically and/or electronically couple the connecting elements 130 with the package substrate 730. Another electronic device may be mounted to the package substrate 730. For example, the processing device 710 is mounted to the package substrate 730 to form a co-packaged optical device. As is illustrated in FIG. 7, the processing device 710 is communicatively connected with the photonics device 720 via metal layers and vias within the package substrate 730 and the connecting elements of the photonics device 720.

As is described above, a photonics device integrates edge coupling and surface coupling techniques to provide a device having the wavelength independency of edge coupling, while allowing manufacturing techniques developed for surface coupling to be applied, increasing the manufacturing throughput and yield. A coupling device is mounted within recesses of a substrate of the photonics device to guide an edge coupled optical signal to be output via a surface coupled optical device, improving the manufacturability and performance of the photonics device.

While the foregoing is directed to specific examples, other and further examples may be devised without departing from the basic scope thereof, and the scope thereof is determined by the claims that follow.

What is claimed is:

1. A photonics device comprising:
a device and dielectric layer comprising a first recess within a first surface of the device and dielectric layer and a second recess within the first surface of the device and dielectric layer; and
a first coupling device mounted to the first surface of the device and dielectric layer, the first coupling device comprising a first mounting element and a first extended region, wherein the first mounting element is disposed within the first recess and the first extended region is disposed within the second recess, and wherein the first extended region is configured to reflect an optical signal through the device and dielectric layer.

2. The photonics device of claim 1, wherein the device and dielectric layer further comprises a third recess and the first coupling device further comprises a second mounting element, wherein the second mounting element is disposed within the third recess.

3. The photonics device of claim 1, wherein a reflective element is disposed on the first extended region.

4. The photonics device of claim 1 further comprising connecting elements disposed on the first surface of the device and dielectric layer, wherein the connecting elements extend a first distance from the first surface of the device and dielectric layer and a substrate of the first coupling device extends a second distance from the first surface of the device and dielectric layer, and wherein the first distance is greater than the second distance.

5. The photonics device of claim 1 further comprising a substrate disposed on a second surface of the device and dielectric layer, wherein the second surface is opposite the first surface.

6. The photonics device of claim 5 further comprising:
a second coupling device mounted to the substrate, the second coupling device comprising a second reflective element configured to reflect the optical signal received from the first extended region.

7. The photonics device of claim 6, wherein the first coupling device further comprises a third reflective element, and the second coupling device further comprises a fourth reflective element, and wherein the third reflective element reflects the optical signal received from the second reflective element, and the fourth reflective element reflects the optical signal received form the third reflective element.

8. A co-packaged device comprising:
a package substrate;
an integrated circuit device mounted to the package substrate; and
a photonics device mounted to the package substrate and connected to the integrated circuit device, wherein the photonics device comprises:
a device and dielectric layer comprising a first recess within a first surface of the device and dielectric layer and a second recess within the first surface of the device and dielectric layer; and
a first coupling device mounted to the first surface of the device and dielectric layer, the first coupling device comprising a first mounting element and a first extended region, wherein the first mounting element is disposed within the first recess and the first extended region is disposed within the second recess, and wherein the first extended region is configured to reflect an optical signal through the device and dielectric layer.

9. The co-packaged device of claim 8, wherein the device and dielectric layer further comprises a third recess and the first coupling device further comprises a second mounting element, wherein the second mounting element is disposed within the third recess.

10. The co-packaged device of claim 8, wherein a reflective element is disposed on the first extended region.

11. The co-packaged device of claim 8, wherein the photonics device further comprises connecting elements disposed on the first surface of the device and dielectric layer and mounted to the package substrate, wherein the connecting elements extend a first distance from the first surface of the device and dielectric layer and a substrate of the first coupling device extends a second distance from the first surface of the device and dielectric layer, and wherein the first distance is greater than the second distance.

12. The co-packaged device of claim 8, wherein the photonics device further comprises a substrate disposed on a second surface of the device and dielectric layer, wherein the second surface is opposite the first surface.

13. The co-packaged device of claim 12 further comprising:
a second coupling device mounted to the substrate, the second coupling device comprising a second reflective element configured to reflect the optical signal received from the first extended region.

14. The co-packaged device of claim 13, wherein the first coupling device further comprises a third reflective element, and the second coupling device further comprises a fourth reflective element, and wherein the third reflective element reflects the optical signal received from the second reflective element, and the fourth reflective element reflects the optical signal received form the third reflective element.

15. A computer system comprising:
computing devices; and
a co-packaged device coupled to the computing devices and configured to communicate signals to and from the computing devices, the co-packaged device comprising:
a package substrate;
an integrated circuit device mounted to the package substrate; and
a photonics device mounted to the package substrate and connected to the integrated circuit device, wherein the photonics device comprises:
a device and dielectric layer comprising a first recess within a first surface of the device and dielectric layer and a second recess within the first surface of the device and dielectric layer; and
a first coupling device mounted to the first surface of the device and dielectric layer, the first coupling device comprising a first mounting element and a first extended region, wherein the first mounting element is disposed within the first recess and the first extended region is disposed within the second recess, and wherein the first extended region is configured to reflect an optical signal through the device and dielectric layer.

16. The computing system of claim 15, wherein the device and dielectric layer further comprises a third recess and the first coupling device further comprises a second mounting element, wherein the second mounting element is disposed within the third recess.

17. The computing system of claim 15, wherein the photonics device further comprises connecting elements disposed on the first surface of the device and dielectric layer and mounted to the package substrate, wherein the connecting elements extend a first distance from the first surface of the device and dielectric layer and a substrate of the first coupling device extends a second distance from the first surface of the device and dielectric layer, and wherein the first distance is greater than the second distance.

18. The computing system of claim 15, wherein the photonics device further comprises a substrate disposed on a second surface of the device and dielectric layer, wherein the second surface is opposite the first surface.

19. The computing system of claim 18, wherein the co-packaged device further comprises:
a second coupling device mounted to the substrate, the second coupling device comprising a second reflective element configured to reflect the optical signal received from the first extended region.

20. The computing system of claim 19, wherein the first coupling device further comprises a third reflective element, and the second coupling device further comprises a fourth reflective element, and wherein the third reflective element reflects the optical signal received from the second reflective element, and the fourth reflective element reflects the optical signal received form the third reflective element.
